(19) United States
(12) Patent Application Publication
(10) Pub. No.: US 2008/0180983 A1
(43) Pub. Date: Jul. 31, 2008

(54) SEMICONDUCTOR DEVICE WITH A PLURALITY OF DIFFERENT ONE TIME PROGRAMMABLE ELEMENTS

(75) Inventor: Joerg Vollrath, Olching (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/021,750

(22) Filed: Jan. 29, 2008

(30) Foreign Application Priority Data
Jan. 29, 2007 (DE) 10 2007 004 311.4

(51) Int. Cl. G11C 17/00

(52) U.S. Cl. 365/96

(57) ABSTRACT

A semiconductor device and method with a plurality of different one time programmable elements. One embodiment provides a semiconductor device having a plurality of different one time programmable elements that form a group of one time programmable elements, wherein at least one bit of information is jointly stored by the plurality of different one time programmable elements of the group.

### CROSS-REFERENCE TO RELATED APPLICATIONS

This Utility Patent Application claims priority to German Patent Application No. DE 10 2007 004 311.4 filed on Jan. 29, 2007, which is incorporated herein by reference.

### BACKGROUND

The invention relates to a semiconductor device with a plurality of different one time programmable elements, to a method for programming a semiconductor device, and to a method for operating a semiconductor device.

Semiconductor devices, e.g., corresponding, integrated (analog or digital) computing circuits, semiconductor memory devices such as, for instance, functional memory devices (PLAs, PALs, etc.) and table memory devices (e.g., ROMs or RAMs, SRAMs and DRAMs), etc. are subject to comprehensive tests during and after their manufacturing processes.

For the common manufacturing of a plurality of (in general identical) semiconductor devices, a wafer (i.e. a thin disc of monocrystalline silicon) is used. The wafer is processed appropriately (e.g., subject successively to a plurality of coating, exposure, etching, diffusion, and implantation processes, etc.), and subsequently e.g., sawn apart (or e.g., scratched, and broken), so that the individual devices are then available.

During the manufacturing of semiconductor devices (e.g., of DRAMS (Dynamic Random Access Memories or dynamic read-write memories)), in one embodiment DDR—DRAMs (Double Data Rate—DRAMs)—even before all the desired, above-mentioned processes were performed on the wafer—(i.e. already in a semi-finished state of the semiconductor devices) the (semi-finished) devices (that are still available on the wafer) may be subject to appropriate tests at one or a plurality of test stations by using one or a plurality of test devices (e.g., kerf measurements at the wafer kerf).

After the finishing of the semiconductor devices (i.e. after the performing of all the above-mentioned wafer processes), the semiconductor devices are subject to further tests at one or a plurality of (further) test stations—for instance, by using appropriate (further) test devices, the finished devices—that are still available on the wafer—may be tested appropriately (so-called “wafer tests”).

Correspondingly, one or a plurality of further tests (at corresponding further test stations, and by using appropriate, further test devices) may be performed, for instance, after the incorporation of the semiconductor devices in the corresponding semiconductor device packages, and/or e.g., after the incorporation of the semiconductor device packages (along with the respectively included semiconductor devices) in corresponding electronic modules, e.g., memory modules (“module tests”).

Based on the results of the above-mentioned tests it is possible to perform appropriate parameter settings with the above-mentioned semiconductor devices (“trimming”).

For instance—by using appropriate laser fuse methods or appropriate electric fuse methods—reference voltages and/or reference currents may be trimmed such that they correspond as exactly as possible to respectively predetermined target values.

In one embodiment—e.g., also on the basis of the results of the above-mentioned tests (and/or of corresponding further tests), and/or also by using appropriate laser fuse methods or appropriate electric fuse methods—corresponding (redundant) elements/chip regions/chip function blocks may be activated on the semiconductor devices (and e.g., corresponding elements/chip regions/chip function blocks that were tested to be defective may be deactivated).

In a laser fuse method, it is possible—on wafer level—to burn away portions of a one time programmable element, e.g., of a corresponding laser fuse resistor, by using a laser beam, and it is thus possible to place the laser fuse resistor from a conductive, first state (“non-programmed state”) in a non-conductive, second state (“programmed state”).

The conductive state may correspond, for instance, to a stored bit “0” (or “1”), and the non-conductive state, for instance, to a stored bit “1” (or “0”).

Correspondingly similar, in an electrical fuse method it is possible, by applying a corresponding programming current pulse to a one time programmable element, e.g., a corresponding E-fuse resistor, to fuse or burn through the resistor. Thus—again—the resistor is placed from a conductive, first state (“non-programmed” state) in a non-conductive, second state (“programmed state”).

Electric fuse methods may, as compared to laser fuse methods, also be performed in relatively late stages of the manufacturing process, e.g., only after the incorporation of a semiconductor device in a corresponding semiconductor device package, and/or, for instance, only after the incorporation of a semiconductor device package (along with the incorporated semiconductor device) in a corresponding electronic module, etc.

In conventional semiconductor devices, either a laser fuse resistor or an e-fuse resistor is used for activating a corresponding (redundant) element/chip region/chip function block.

Frequently, a first (redundant) element/chip region/chip function block is provided for one and the same function, which is adapted to be activated—in a first repair process on wafer level—by using an appropriate laser fuse resistor, and additionally a second (redundant) element/chip region/chip function block which is adapted to be activated—later, in a second repair process—by using an appropriate e-fuse resistor.

This is relatively expensive.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

The present embodiments provide a novel semiconductor device, in one embodiment a DRAM, having a plurality of different one time programmable elements, and a method for programming, as well as a method for operating a semiconductor device, in one embodiment a DRAM.

In accordance with one embodiment, there is provided a semiconductor device having a plurality of different one time programmable elements that form a group of one time programmable elements, wherein the plurality of different one time programmable elements of the group jointly store at least one bit of information.

In one embodiment, a first of the plurality of different one time programmable elements is a laser fuse resistor, and a second of the plurality of different one time programmable elements is an e-fuse resistor.

In one embodiment, the laser fuse resistor and the e-fuse resistor may be connected in parallel.

FIG. 1A illustrates a schematic representation of stations that are run through during the manufacturing of corresponding semiconductor devices, and of a plurality of test devices used for testing the semiconductor devices.

FIG. 1B illustrates a schematic representation of further stations that are run through during the manufacturing of corresponding semiconductor devices, and of a plurality of further test devices used for testing the semiconductor devices.

FIG. 2 illustrates an exemplary schematic representation of a section of a semiconductor device having a plurality of different one time programmable elements in accordance with one embodiment.

FIG. 3 illustrates an exemplary schematic representation of a section of a semiconductor device having a plurality of different one time programmable elements in accordance with one embodiment.

FIG. 4 illustrates an exemplary schematic representation of a section of a semiconductor device having a plurality of different one time programmable elements in accordance with one embodiment.

FIG. 5 illustrates an exemplary schematic representation of a section of a semiconductor device having a plurality of different one time programmable elements in accordance with one embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

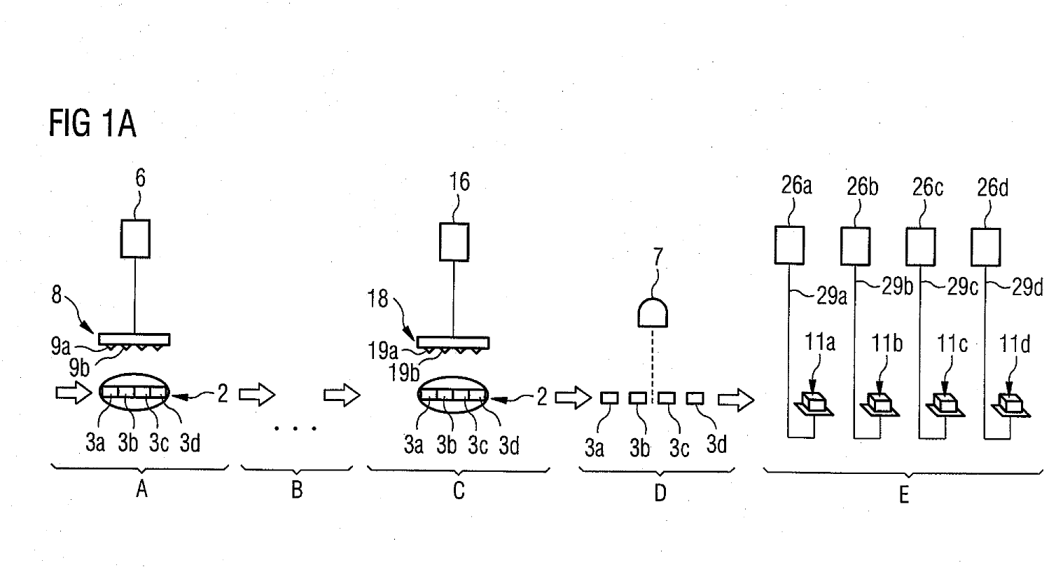

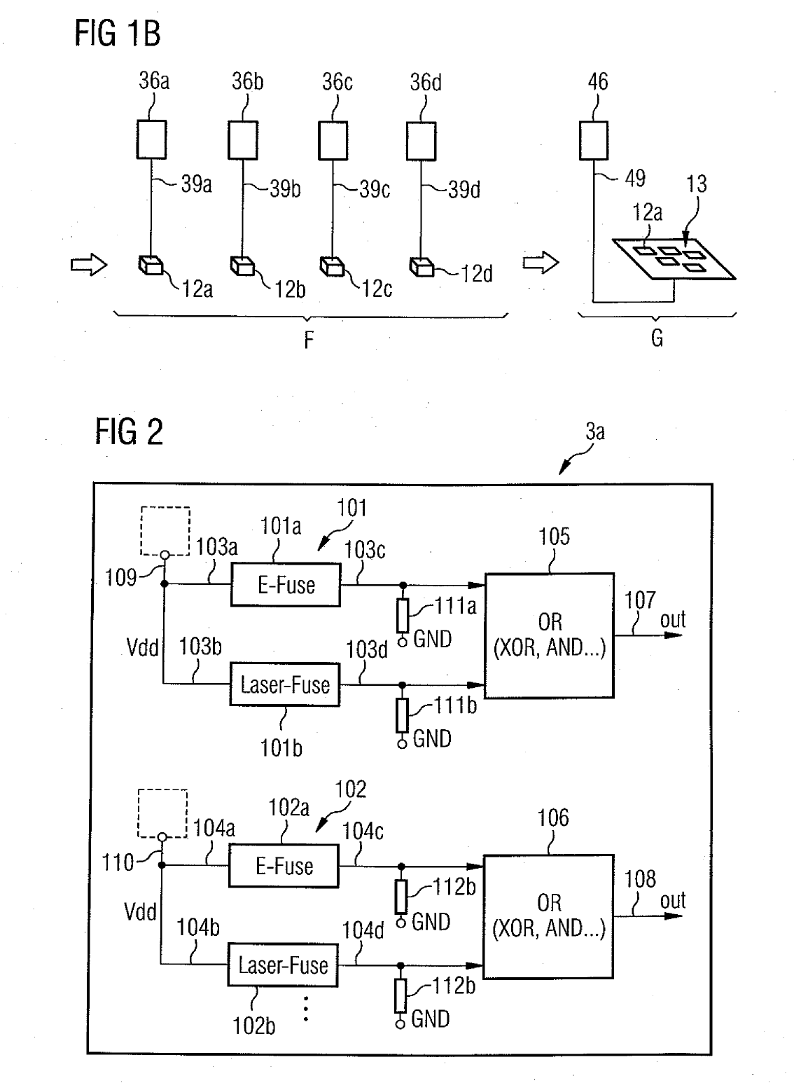

FIGS. 1A and 1B illustrate—schematically—some (out of a plurality of further, not illustrated) stations A, B, C, D, E, F, G that are run through by corresponding semiconductor devices 3a, 3b, 3c, 3d during the manufacturing of semiconductor devices 3a, 3b, 3c, 3d.

The semiconductor devices 3a, 3b, 3c, 3d may, for instance, be corresponding, integrated (analog or digital) computing circuits, and/or semiconductor memory devices such as e.g., functional memory devices (PLAs, PALs, etc.) or table memory devices (e.g., ROMs or RAMS), in one embodiment SRAMs or DRAMs (here e.g., DRAMs (Dynamic Random Access Memories or dynamic write-read memories) with double data rate (DDR-DRAMs=Double Data Rate−DRAMs), high-speed DDR-DRAMs).

During the manufacturing of the semiconductor devices 3a, 3b, 3c, 3d, an appropriate silicon disc or an appropriate wafer 2 is—e.g., at stations that are positioned upstream or downstream of the station A illustrated in FIG. 1A (e.g., at the station B that is positioned downstream of the station A, and at a plurality of further, not illustrated stations (that are positioned upstream or downstream of the station A)—subject to corresponding, conventional coating, exposure, etching, diffusion, and/or implantation processes, etc.

The station A serves to subject the semiconductor devices 3a, 3b, 3c, 3d—which are still available on the wafer 2—to one or a plurality of test methods—e.g., kerf measurements at the wafer kerf—by using a test device 6 (namely—as results from the above statements—even before all the desired, above-mentioned processes were performed at the wafer 2 (i.e. already in a semi-finished state of the semiconductor devices 3a, 3b, 3c, 3d).

The voltages/currents or test signals required at the station A for testing the semiconductor devices 3a, 3b, 3c, 3d on the wafer 2 are generated by the test device 6 and are applied to corresponding connections of the semiconductor devices 3a, 3b, 3c, 3d by using a semiconductor device test card 8 or probe card 8 (more exactly: by using corresponding contact needles 9a, 9b provided at the probe card 8) which is connected with the test device 6.

From the station A, the wafer 2 is (in one embodiment in a fully automated manner) transported forward to the station B (and from there possibly to a plurality of further—not illustrated—stations) where—as was already mentioned above—the wafer 2 is subject to appropriate, further processes (in one embodiment appropriate coating, exposure, etching, diffusion, and/or implantation processes, etc.), and/or—correspondingly similar as at the station A—to corresponding further test methods.

After the finishing of the semiconductor devices (i.e. after the performing of all the above-mentioned wafer processes) the wafer 2 is, from the corresponding—last—processing station (e.g., the station B or the further stations positioned downstream thereof)—transported forward to the next station C—in one embodiment in a fully automated manner.

The station C serves to subject the finished semiconductor devices 3a, 3b, 3c, 3d—that are still available on the wafer 2—to one or a plurality of—further—test methods by using a test device 16 (e.g., wafer tests).

The voltages/currents or test signals required at the station C for testing the semiconductor devices 3a, 3b, 3c, 3d on the wafer 2 are generated by the test device 16 and are applied to corresponding connections of the semiconductor devices 3a, 3b, 3c, 3d by using a semiconductor device test card 18 or probe card 18 (more exactly: by using corresponding contact needles 19a, 19b that are provided at the probe card 18) which is connected with the test device 16.

From the station C, the wafer 2 is (in one embodiment in a fully automated manner) transported forward to the next station D, and is there (after the wafer 2 was laminated with a film in a per se known manner) sawn apart (or e.g., scratched, and broken) by using an appropriate machine 7, so that the semiconductor devices 3a, 3b, 3c, 3d are then available individually (as corresponding semiconductor device chips).

Prior to being transported forward to the station D, the wafer 2—or the devices 3a, 3b, 3c, 3d available thereon—may be subject to one or a plurality of further test methods at one or a plurality of stations corresponding to the station C.

After the sawing apart of the wafer 2 at the station D, every single device or every single chip 3a, 3b, 3c, 3d is then (in one embodiment—again—in a fully automated manner) loaded into an appropriate carrier 11a, 11b, 11c, 11d or an appropriate outer package 11a, 11b, 11c, 11d, and the semiconductor devices 3a, 3b, 3c, 3d—that are loaded into the carriers 11a, 11b, 11c, 11d—are subject to one or a plurality of further test methods (e.g., carrier tests) at one or a plurality of (further) test stations—e.g., the station E illustrated in FIG. 1A.

To this end, the carriers 11a, 11b, 11c, 11d are introduced into corresponding carrier sockets or carrier adapters, respectively, which are connected with one (or a plurality of) corresponding test device(s) 26a, 26b, 26c, 26d via corresponding lines 29a, 29b, 29c, 29d.

The voltages/currents or test signals required at the station E for testing the semiconductor devices 3a, 3b, 3c, 3d in the carriers 11a, 11b, 11c, 11d are generated by the test device(s) 26a, 26b, 26c, 26d and applied to corresponding connections of the semiconductor devices 3a, 3b, 3c, 3d via the carrier sockets that are connected with the test device(s) 26a, 26b, 26c, 26d via the lines 29a, 29b, 29c, 29d, and the carriers 11a, 11b, 11c, 11d that are connected thereto.

From the station E, the semiconductor devices 3a, 3b, 3c, 3d are (in one embodiment in a fully automated manner) transported forward to one or a plurality of—not illustrated—station(s) where the semiconductor devices 3a, 3b, 3c, 3d are incorporated into appropriate packages 12a, 12b, 12c, 12d (e.g., appropriate plug or surface-mountable device packages, etc.).

As is illustrated in FIG. 1B, the semiconductor devices 3a, 3b, 3c, 3d—that are incorporated in the packages 12a, 12b, 12c, 12d—are then transported forward to one (or a plurality of) further test station(s)—e.g., the station F illustrated in FIG. 1B—, and are subject to one or a plurality of further test methods there.

To this end, the semiconductor device packages 12a, 12b, 12c, 12d are introduced into appropriate device package sockets or device package adapters which are—via corresponding lines 39a, 39b, 39c, 39d—connected with one (or a plurality of) corresponding test device(s) 36a, 36b, 36c, 36d.

The voltages/currents or test signals required at the station F for testing the semiconductor devices 3a, 3b, 3c, 3d—that are incorporated in the packages 12a, 12b, 12c, 12d—are generated by the test device(s) 36a, 36b, 36c, 36d and are applied to corresponding connections of the semiconductor devices 3a, 3b, 3c, 3d via the package sockets that are, via the lines 39a, 39b, 39c, 39d, connected with the test device(s) 36a, 36b, 36c, 36d, and the device packages 12a, 12b, 12c, 12d that are connected thereto.

From the station F, the semiconductor devices 3a, 3b, 3c, 3d incorporated in the packages 12a, 12b, 12c, 12d may then—optionally—be transported forward to one or a plurality of—not illustrated—further station(s) where a corresponding semiconductor device package (e.g., the package 12a together with the semiconductor device 3a incorporated therein) is—along with further devices (analog or digital computing circuits, and/or semiconductor memory devices, e.g., PLAs, PALs, ROMs, RAMS, in one embodiment SRAMs or DRAMs, etc.)—connected to a corresponding electronic module 13—e.g., a printed circuit board.

As is illustrated in FIG. 1B, the electronic module 13 (and thus also the semiconductor devices 3a that are connected to the electronic module 13 (and are incorporated in a corresponding package 12a)) may then—optionally—be transported forward to one (or a plurality of) further test station(s)—e.g., the station G illustrated in FIG. 1B—, and be subject there to one or a plurality of further test methods (in one embodiment module tests).

The voltages/currents or test signals required at the station G for testing the module 13 (and thus the semiconductor devices 3a incorporated therein) are, for instance, generated by a test device 46 and are applied, via a line 49, to the electronic module 13 and thus to the corresponding connections of the corresponding semiconductor devices 3a that are incorporated therein.

Based on the results of the above-mentioned test methods (or on the results of a part of the above-mentioned test methods), appropriate parameter settings may, for instance, be performed with the above-mentioned semiconductor devices 3a, 3b, 3c, 3d (“trimming”).

For instance—by using the fuse method that will be explained in more detail in the following, or by using a correspondingly similar fuse method—reference voltages and/or reference currents may be trimmed such that they correspond as exactly as possible to respectively predetermined target values.

The parameter target values are, for instance, chosen such that the semiconductor devices 3a, 3b, 3c, 3d operate as “optimally” as possible with the corresponding parameter target values, e.g., with respect to reliability and/or rate, and/or power consumption, etc.

In one embodiment—e.g., also on the basis of the results of the above-mentioned test methods (or of the results of part of the above-mentioned test methods, and/or of corresponding further test methods, etc.), and/or also by using the fuse method that will be explained in more detail in the following, or a correspondingly similar fuse method—corresponding (redundant) elements/chip regions/chip function blocks on the semiconductor devices 3a, 3b, 3c, 3d may be activated (and/or e.g., corresponding elements/chip regions/chip function blocks—that were tested to be defective in the above-mentioned test methods—may be deactivated and be replaced by the above-mentioned activated redundant elements/regions/blocks).

The above-mentioned activatable or deactivatable (redundant) elements/chip regions/chip function blocks may, for instance, be corresponding (redundant) single memory cells, or e.g., chip function blocks having one or a plurality of (redundant) memory cell arrays, i.e. a plurality of (redundant) memory cells, and or any other (redundant) elements/chip regions/chip function blocks, e.g., row or column logic (or parts thereof), voltage supply elements, input/output (I/O) blocks, interface units (or parts thereof), etc.

As is schematically illustrated in FIG. 2, and as will be explained in more detail in the following, for trimming the semiconductor device 3a, 3b, 3c, 3d, or for activating the above-mentioned (redundant) elements/chip regions/chip function blocks (or for deactivating the above-mentioned elements/chip regions/chip function blocks that were tested to be defective, etc., etc.)—other than conventionally—instead of (one or a plurality of) one time programmable (fuse) elements by using which one respective bit of information is stored, (one or a plurality of) groups 101, 102 of a plurality of different one time programmable elements 101a, 110b, 102a, 102b, in one embodiment fuse elements, may be used, wherein one respective bit of information can be stored with each element group 101, 102 in the manner that will be explained in more detail in the following.

An element group 101, 102 may, for instance—as is illustrated in FIG. 2—each include two one time programmable elements 101a, 101b, 102a, 102b, or In one embodiment, e.g., also more than two one time programmable elements 101a, 101b, 102a, 102b, e.g., three, four, or more than four one time programmable elements.

A plurality of the above-mentioned element groups 101, 102, 1101 may be provided on the semiconductor devices 200, 1200, e.g., more than three, five, or ten element groups, etc.

In addition to the one or several element groups 101, 102, 110—which are each used for storing one bit of information—which each include a plurality of different one time programmable elements 101a, 101b, 102a, 102b, 1101a, 1101b, 1101c, the semiconductor devices 3a, 3b, 3c, 3d may also include one or a plurality of conventional one time programmable elements which are used for storing one respective bit of information, e.g., a plurality of e-fuse resistors, and/or a plurality of laser fuse resistors.

These may then—possibly along with the element groups 101, 102, 1101—e.g., be used for setting or trimming the above-mentioned semiconductor device parameters, e.g., corresponding reference voltages and/or reference currents, or for activating/deactivating the above-mentioned or further (redundant) elements/chip regions/chip function blocks on the semiconductor devices 3a, 3b, 3c, 3d.

For instance, a plurality of conventional e-fuse resistors and/or laser fuse resistors may be provided on the semiconductor devices 3a, 3b, 3c, 3d which are each used for activating/deactivating a corresponding (redundant) element/chip region/chip function block of a first group of (redundant) elements/chip regions/chip function blocks on the semiconductor devices 3a, 3b, 3c, 3d.

Corresponding further (redundant) elements/chip regions/chip function blocks of a second group of (redundant) elements/chip regions/chip function blocks—which is, for instance, smaller in number—on the semiconductor devices 3a, 3b, 3c, 3d may on the contrary—as will be explained in more detail in the following—, instead with an above-mentioned conventional e-fuse resistor or laser fuse resistor, each be activated/deactivated with a corresponding of the above-mentioned element groups 101, 102 illustrated in FIG. 2.

As already indicated above, and as illustrated schematically in FIG. 2, each of the above-mentioned element groups 101, 102 includes two different on time programmable elements 101a, 101b, 102a, 102b, in one embodiment two different fuse elements.

For instance, the first element group 101 may include an e-fuse resistor 101a—that is constructed similar to a conventional e-fuse resistor—, and a laser fuse resistor 101b—that is constructed similar to a conventional laser fuse resistor—, etc.

Correspondingly similar, the second element group 102 may also include an e-fuse resistor 102a—that is constructed similar to a conventional e-fuse resistor, and a laser fuse resistor 102b—that is constructed similar to a conventional laser fuse resistor—, etc.

In the above-mentioned laser fuse resistors 101b, 102b—correspondingly similar as in conventional laser fuse resistors—it is possible, by using a corresponding laser fuse method, to correspondingly burn away portions of an individual resistor 101b, 102b of a respective element group 101, 102 which has, for instance, been selected in the manner explained below, and it is thus possible to place the corresponding laser fuse resistor 101b, 102b from a conductive, first state (“non-programmed state”) in a non-conductive, second state (“programmed state”).

The programming of the laser fuse resistors 101b, 102b of the element groups 101, 102 may, for instance, be performed on wafer level, i.e., for instance, at or before the above-mentioned station A illustrated in FIG. 1A, or at or before the above-mentioned station B, or at or before the above-mentioned station C, etc., or, for instance, also after the sawing apart of the wafer 2 at the above-mentioned station D, etc. (but in general no longer after the incorporation of the semiconductor devices 3a, 3b, 3c, 3d in corresponding carriers 11a, 11b, 11c, 11d or device packages 12a, 12b, 12c, 12d (between the stations D and E and/or between the stations E and F)).

In one embodiment, to one or a plurality of the above-mentioned laser fuse resistors 101b, 102b of the element groups 101, 102, one or a plurality of the above-mentioned e-fuse resistors 101a, 102a of the element groups 101, 102 may also be programmed correspondingly.

For instance—correspondingly similar as in conventional e-fuse resistors—in the e-fuse resistors 101a, 102b of the element group 101, 102 it is possible, by using an appropriate electric fuse method, by applying an appropriate programming current pulse to an individual resistor 101a, 102a of the respective element group 101, 102 which has been selected in the manner explained below, to fuse or burn through the corresponding e-fuse resistor 101a, 102a.

Thus, the corresponding e-fuse resistor 101a, 102a is placed from a conductive, first state (“non-programmed state”) in a non-conductive, second state (“programmed state”).

The programming of the e-fuse resistors 101a, 102a may, for instance, be performed on wafer level, i.e., for instance, at or before the above-mentioned station A illustrated in FIG. 1, or at or before the above-mentioned station B, or at or before the above-mentioned station C, or, for instance, after the sawing apart of the wafer 2 at the above-mentioned station D, or—in one embodiment—only later, e.g., after the incorporation of the semiconductor devices 3a, 3b, 3c, 3d in corresponding carriers 11a, 11b, 11c, 11d, or after the incorporation of the semiconductor devices 3a, 3b, 3c, 3d in corresponding device packages 12a, 12b, 12c, 12d, or else only after the incorporation of a device package 12a along with the semiconductor device 3a incorporated therein in a corresponding electronic module 13 (e.g., at or after the station E, or at or after the station F, or at or after the station G, etc.)).

In a first (initial) state of the element groups 101, 102, all programmable elements 101a, 102a of the respective group 101, 102 are in the above-mentioned first, conductive state (“non-programmed state”).

This first (initial) state of the element groups 101, 102 may, for instance, correspond to a bit “0” (or alternatively: “1”) stored by the respective element group 101, 102.

As results from FIG. 2, the two different one time programmable elements 101a, 101b, 102a, 102b of the respective element group 101, 102 are each connected in parallel.

For instance, as results from FIG. 2, a first connection of the respective e-fuse resistor 101a, 102a may, via a corresponding line 103a, 104a, be connected to a line 109, 110 in the element groups 101, 102.

Correspondingly similar, in the element groups 101, 102, a respective first connection of the respective laser fuse resistor 101b, 102b may, via a corresponding line 103b, 104b—also—be connected to the line 109, 110.

Furthermore, as results from FIG. 2, in the element groups 101, 102, a respective second connection of the respective e-fuse resistor 101a, 101b may, via a corresponding line 103c, 104c, be connected to an evaluation logic circuit 105, 106, in one embodiment to an OR gate, or in one embodiment, e.g., to an XOR gate, or e.g., to an AND gate, etc.

Furthermore, in the element groups 101, 102, a respective second connection of the respective laser fuse resistor 101b, 102b may, via a corresponding line 103d, 104d—also—be connected to the above-mentioned evaluation logic circuit 105, 106.

In addition—as is illustrated in FIG. 2—the respective second connections of the laser fuse and e-fuse resistors 101a, 101b, 102a, 102b of the element groups 101, 102 may, via corresponding resistors 111a, 111b or 112a, 112b, be grounded, i.e. be connected to ground potential (GND).

In one embodiment, the use of the evaluation logic circuits 105, 106 may, for instance, also be waived. The second connections of the respective laser fuse resistors 101b, 102b and of the respective e-fuse resistors 101a, 102a may then be connected directly with each other, or may each be connected to a corresponding output line 107, 108, respectively.

The evaluation logic circuits 105, 106 or OR gates (or alternatively XOR or AND gates) illustrated in FIG. 2 each include two inputs, wherein a respective first input of the respective OR/XOR/AND gate is, for instance, connected to the above-mentioned second connection of the respective e-fuse resistor 101a, 102a via the above-mentioned line 103c, 104c, and a respective second input of the respective OR/XOR/AND gate, for instance, via the above-mentioned line 103d, 104d to the above-mentioned second connection of the respective laser fuse resistor 101b, 102b.

In a further variant, a corresponding converter means may be connected between the lines 103c, 103d, 104c, 104d and the above-mentioned inputs of the evaluation logic circuits 105, 106, which converts the analog value present at the respective line 103c, 103d, 104c, 104d to a corresponding digital value (logic “0” or logic “1”) and transmits it to the corresponding input of the corresponding evaluation logic circuit 105, 106.

As results further from FIG. 2, the output of the respective evaluation logic circuit 105, 106 is connected with the corresponding of the above-mentioned output lines 107, 108.

A supply voltage (here: Vdd) may be connected, for instance, to the above-mentioned line 109 or 110, or—as is illustrated in dashes in FIG. 2—e.g., also a corresponding (redundant) element/chip region/chip function block that is adapted to be activated/deactivated by using the respective element group 101, 102, etc.

Since—as explained above already—in the above-mentioned first (initial) state of the element groups 101, 102 all programmable elements 101a, 101b, 102a, 102b of the respective group 101, 102 are in the above-mentioned first, conductive state (“non-programmed state”), all inputs of the evaluation logic circuits 105, 106 are in the same (first) state.

In one embodiment, at the lines 103c, 103d, 104c, 104d the above-mentioned supply voltage potential Vdd will then be present, or at the inputs of the evaluation logic circuits 105, 106 e.g., a logic “1” (or alternatively a logic “0”), respectively.

The output of the evaluation logic circuits 105, 106—i.e. the output line 107, 108—is thus in a (first) state.

In one embodiment—if the above-mentioned OR gate is used as logic circuit 105, 106—the above-mentioned supply voltage potential Vdd, i.e., for instance, a logic “1” (or alternatively a logic “0”) will be present at the output of the logic circuit 105, 106, or—if the above-mentioned XOR gate is used as logic circuit 105, 106—the above-mentioned ground potential GND, i.e., for instance, a logic “0” (or alternatively a logic “1”) will be present at the output of the logic circuit 105, 106, or—if the above-mentioned AND gate is used as logic circuit 105, 106—the above-mentioned supply voltage potential Vdd, i.e., for instance, a logic “1” (or alternatively a logic “0”) will be present at the output of the logic circuit 105, 106, etc.

In the first (initial) state of the element groups 101, 102, they thus store, for instance—in one embodiment if an XOR gate is used as logic circuit 105, 106—a bit “0” (or alternatively: a bit “1”).

If instead—in one embodiment if an XOR gate is used as logic circuit 105, 106—a bit “1” (or alternatively: a bit “0”) is to be stored by a corresponding element group 101, 102, the respective element group 101, 102 is placed from the above-mentioned first (initial) state in a second state.

To this end—as was already explained above—optionally either the respective laser fuse resistor 101b, 102b of the respective element group 101, 102 or—in one embodiment also only in a relatively late stage of the manufacturing process, e.g., after the incorporation of the corresponding semiconductor device 3a, 3b, 3c, 3d in the corresponding device package 12a, 12b, 12c, 12d—the respective e-fuse resistor 101a, 102a of the respective element group 101, 102 may be placed from the above-mentioned conductive, first state (“non-programmed state”) in a non-conductive, second state (“programmed state”).

For instance, in the respective laser fuse resistor 101b, 102b of the respective element group 101, 102, it is possible, by using an appropriate laser fuse method, to burn away portions of the respective laser fuse resistor 101b, 102b by using a laser beam, and to thus place the respective laser fuse resistor 101b, 102b from a conductive, first state (“non-programmed state”) in a non-conductive, second state (“programmed state”).

In one embodiment, in the respective e-fuse resistor 101a, 102a of the respective element group 101, 102 it is instead possible, by using an appropriate electric fuse method, by applying an appropriate programming current pulse to the respective e-fuse resistor 101a, 102a of the respective element group 101, 102, to fuse or burn through the corresponding e-fuse resistor 101a, 102a (and to thus place the corresponding e-fuse resistor 101a, 102a from a conductive, first state (“non-programmed state”) in a non-conductive, second state (“programmed state”).

The corresponding programming current pulse may, for instance, in reaction to a corresponding programming instruction signal applied to a control circuit, be automatically generated by the control circuit and be applied to the corresponding e-fuse resistor 101a, 102a.

In the above-mentioned second state of the element group 101, 102, thus either the e-fuse resistor 101a, 102a or the laser fuse resistor 101b, 102b of the respective element group 101, 102 is in the above-mentioned second, non-conductive state (“programmed state”), and the respectively other resistor of the respective element group 101, 102 in the above-mentioned first, conductive state (“non-programmed state”).

For this reason—if the e-fuse resistor 101a, 102a was programmed—the first input, or—if the laser fuse resistor 101b, 102b was programmed—the second input of the evaluation logic circuit 105, 106 is in a (second) state differing from the above-mentioned first state, which corresponds, for instance, to a logic “0” (or alternatively a logic “1”), and the respectively other input of the evaluation logic circuit 105, 106 continues to be in the above-mentioned first state that corresponds, for instance, to a logic “1” (or alternatively a logic “0”).

The output of the evaluation logic circuit 105, 106—i.e. the output line 107, 108—is then—if an XOR gate is used as logic circuit 105, 106 (see below)—placed from the above-mentioned first to a different (second) state (logic “1” (or alternatively logic “0”)).

In one embodiment—if the above-mentioned OR gate is used as logic circuit 105, 106—the above-mentioned supply voltage potential Vdd continues to be present at the output of the logic circuit 105, 106, i.e., for instance, a logic “1” (or alternatively a logic “0”), or—if the above-mentioned XOR gate is used as logic circuit 105, 106—the above-mentioned supply voltage potential Vdd is present at the output of the logic circuit 105, 106, i.e., for instance, a logic “1” (or alternatively a logic “0”), or—if the above-mentioned AND gate is used as logic circuit 105, 106—the above-mentioned ground potential GND is present at the output of the logic circuit 105, 106, i.e., for instance, a logic “0” (or alternatively a logic “1”), etc.

In the above-mentioned second state of the element groups 101, 102 they thus store—if an XOR gate is used as logic circuit 105, 106—a bit “1” (or alternatively: a bit “0”).

If the element group 101, 102 is placed from the above-mentioned second state in a third state in which both respective resistors 101a, 101b or 102a, 102b are in the above-mentioned non-conductive, second state (“programmed state”), the respective element group—if an XOR gate is used as logic circuit 105, 106 (see below)—again stores a bit “0” (or alternatively: a bit “1”):

In this case, both the first input and the second input of the evaluation logic circuit 105, 106 are in the above-mentioned second state that corresponds, for instance, to a logic “0” (or alternatively a logic “1”).

Then—if the above-mentioned OR gate is used as logic circuit 105, 106—the above-mentioned ground potential GND, i.e., for instance, a logic “0” (or alternatively a logic “1”) is again present at the output of the logic circuit 105, 106, or—if the above-mentioned XOR gate is used as logic circuit 105, 106—the above-mentioned ground potential GND, i.e., for instance, a logic “0” (or alternatively a logic “1”) is present at the output of the logic circuit 105, 106, or—if the above-mentioned AND gate is used as logic circuit 105, 106—the above-mentioned ground potential GND, i.e., for instance, a logic “0” (or alternatively a logic “1”) is present at the output of the logic circuit 105, 106, etc.

Depending on the state of the output of the evaluation logic circuit 105, 106 or of the output line 107, 108, respectively—or depending on the state of the bit stored by the respective element group 101, 102—an activatable/deactivatable (redundant) element/chip region/chip function block, etc. assigned to the respective element group may be placed in an activated or a deactivated state (e.g., with a stored bit “1” in an activated (or alternatively deactivated) state, and with a stored bit “0” in a deactivated (or alternatively activated) state).

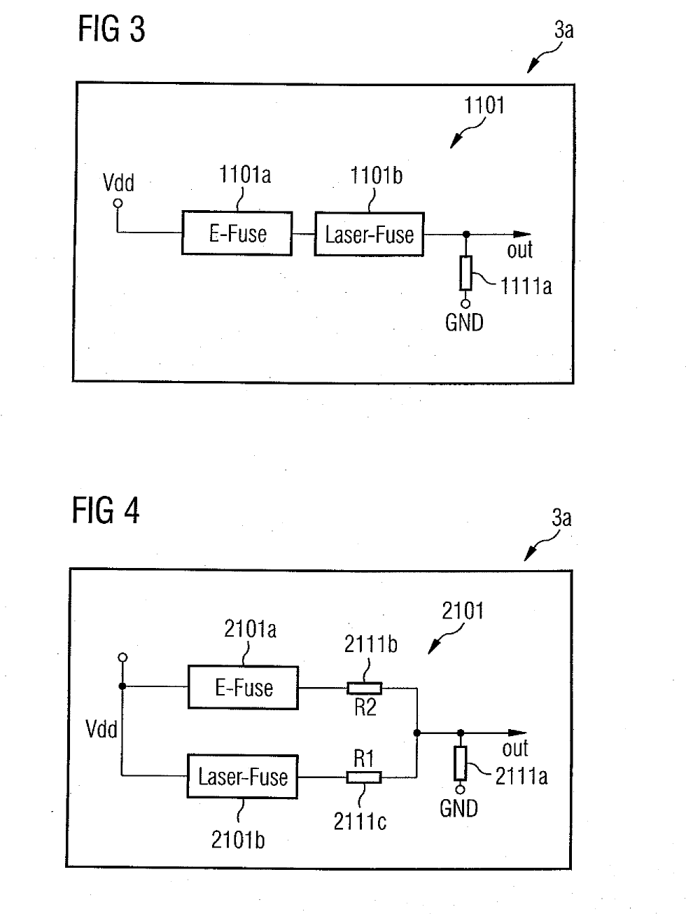

FIG. 3 is an exemplary schematic representation of a section of a semiconductor device 3a with a plurality of (here: two) different one time programmable elements 1101a, 1101b in accordance with a further embodiment.

The two different one time programmable elements 1101a, 1101b form together an element group 1101 by using which it is possible to store a bit of information in the manner that will be explained in more detail in the following.

As results from FIG. 3, the element group 1101 may include an e-fuse resistor 1101a—that is constructed correspondingly similar to a conventional e-fuse resistor—, and a laser fuse resistor 1101b—that is constructed correspondingly similar to a conventional laser fuse resistor—, etc.

As results further from FIG. 3, the two different one time programmable elements 1101a, 1101b of the element group 1101 are connected in series.

For instance, a first connection of the e-fuse resistor 101a may be connected to a supply voltage (here: Vdd), and a second connection of the e-fuse resistor 1101a to a first connection of the laser fuse resistor 1101b.

A second connection of the laser fuse resistor 1101b may be grounded via a corresponding resistor 1111a, i.e. be connected to ground potential (GND).

Furthermore, a corresponding converter means may be connected to the second connection of the laser fuse resistor 1101b, which converts the analog value present at the second connection of the laser fuse resistor 1101b to a corresponding digital value (logic “0”, or logic “1”).

In a first (initial) state of the element group 1101, all programmable elements 1101a, 1101b may be in the above-mentioned first, conductive state (“non-programmed state”).

At the second connection of the laser fuse resistor 1101b—i.e. at the output of the element group 1101—the above-mentioned supply voltage potential Vdd or a logic “1” (or alternatively a logic “0”) will then be present.

In the first (initial) state of the element group 1101, it thus stores, for instance, a bit “1” (or alternatively: a bit “0”).

If a bit “0” (or alternatively: a bit “1”) is to be stored by the element group 1101 instead, the element group is placed from the above-mentioned first (initial) state in a second state.

To this end—correspondingly similar as explained above—optionally either the laser fuse resistor 1001b, or—in one embodiment also only in a relatively late stage of the manufacturing process—the e-fuse resistor 1101a of the element group 1101 may be placed from the above-mentioned conductive, first state (“non-programmed state”) in a non-conductive, second state (“programmed state”).

In the above-mentioned second state of the element group 1101, thus either the e-fuse resistor 1101a or the laser fuse resistor 1101b is in the above-mentioned second, non-conductive state (“programmed state”), and the respectively other resistor in the above-mentioned first, conductive state (“non-programmed state”).

At the second connection of the laser fuse resistor 1101b—i.e. at the output of the element group 1101—the above-mentioned ground potential GND or a logic “0” (or alternatively a logic “1”) will then be present.

In the above-mentioned second state of the element group 1101, it thus stores a bit “0” (or alternatively: a bit “1”).

If the element group 1101 is placed from the above-mentioned second state in a third state in which both resistors 1101a, 1101b are in the above-mentioned non-conductive, second state (“programmed state”), the element group 1101 continues to store a bit “0” (or alternatively: a bit “1”) since in this case the above-mentioned ground potential GND is still present at the second connection of the laser fuse resistor 1101b—i.e. at the output of the element group 1101.

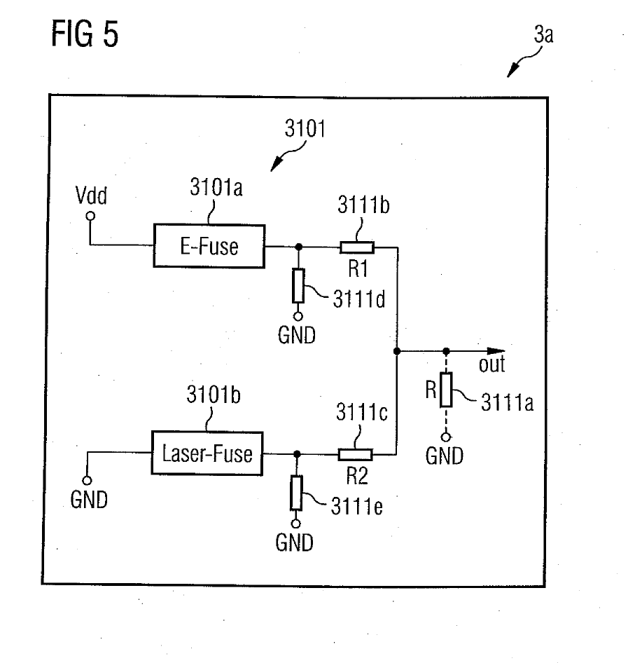

FIG. 4 illustrates an exemplary schematic representation of a section of a semiconductor device 3a with a plurality of (here: two) different one time programmable elements 2101a, 2101b in accordance with one embodiment.

The two different one-time programmable elements 2101a, 2101b form together an element group 2101 by using which a bit of information—or alternatively also a plurality of bits of information (see below)—may be stored in the above-explained manner.

As results from FIG. 4, the element group 2101 may include an e-fuse resistor 2101a—that is constructed correspondingly similar to a conventional e-fuse resistor—, and a laser fuse resistor 2101b—that is constructed correspondingly similar to a conventional laser fuse resistor, etc.

As results further from FIG. 4, the two different one time programmable elements 2101a, 2101b of the element group 2101 are connected in parallel.

For instance, a first connection of the e-fuse resistor 2101a and a first connection of the laser fuse resistor 2101b may be jointly connected to a supply voltage (here: Vdd).

Furthermore, a second connection of the e-fuse resistor 2101a may be connected to a first connection of a resistor 2111b with an ohmic resistance R2, and a second connection of the laser fuse resistor 2101b to a first connection of a resistor 2111c with an ohmic resistance R1.

The second connection of the resistor 2111b and the second connection of the resistor 2111c may be connected with each other and be grounded via a corresponding resistor 2111a (with an ohmic resistance R), i.e. be connected to ground potential (GND).

Furthermore, the second connections of the resistors 2111b, 2111c may—jointly—be connected to a corresponding converter means that converts the analog value present at the second connections of the resistors to a corresponding digital one-bit-value (“0”, or “1”), or—alternatively—to a corresponding digital two-bit value (e.g., “00”, or “01”, or “10”, or “11” (see below)).

In a first (initial) state of the element group 2101, all programmable elements 2101a, 2101b may be in the above-mentioned, conductive state (“non-programmed state”).

At the second connections of the resistors 2111b, 2111c—i.e. at the output of the element group 2101—the following voltage potential Vout will then be present:

Vout=Vdd×R/(R+(R1×R2/(R1+R2)))

This voltage potential may, for instance, be converted to a one-bit value “1” (or alternatively e.g., “0”), or—alternatively—e.g., to a two-bit value “11” (or alternatively e.g., “00”, etc.) by the above-mentioned converter means.

In the first (initial) state of the element group 2101, it thus stores, for instance, a bit “1” (or alternatively: a bit “0”).

If a different one- (or two-) bit-value is to be stored instead by the element group 2101, the element group may be placed from the above-mentioned first (initial) state in a second state.

To this end—correspondingly similar as explained above—optionally either the laser fuse resistor 2101b, or—in one embodiment also only in a relatively late stage of the manufacturing process—the e-fuse resistor 2101a of the element group 2101 may be placed from the above-mentioned conductive, first state (“non-programmed state”) in a non-conductive, second state (“programmed state”).

In the above-mentioned second state of the element group 2101, thus either the e-fuse resistor 2101a or the laser fuse resistor 2101b is in the above-mentioned second, non-conductive state (“programmed state”), and the respectively other resistor in the above-mentioned first, conductive state (“non-programmed state”).

At the second connections of the resistors 2111b, 2111c—i.e. at the output of the element group 2101—if the e-fuse resistor 2101a is programmed—the following voltage potential Vout will then be present:

Vout=Vdd×R/(R1+R)

This voltage potential may be converted by the above-mentioned converter means, for instance, to a one-bit value “0” (or alternatively e.g., “1”), or—alternatively—e.g., to a two-bit value “01” (or alternatively e.g., “10”, etc.).

If the laser fuse resistor 2101b is programmed instead of the e-fuse resistor 2101a, the following voltage potential Vout will be present at the second connections of the resistors 2111b, 2111c—i.e. at the output of the element group 2101:

Vout=Vdd×R/(R2+R)

This voltage potential may be converted by the above-mentioned converter means, for instance, to a one-bit value “0” (or alternatively e.g., “1”), or—alternatively—e.g., to a two-bit value “10” (or alternatively e.g., “01”, etc.).

If the element group 2101 is placed from the above-mentioned second state in a third state in which both resistors 2101a, 2101b are in the above-mentioned non-conductive, second state (“programmed state”), the ground potential GND is present at the second connections of the resistors 2111b, 2111c—i.e. at the output of the element group 2101.

This voltage potential may be converted by the above-mentioned converter means, for instance, to a one-bit value “0” (or alternatively e.g., “1”), or—alternatively—e.g., to a two-bit value “00” (or alternatively e.g., “11”, etc.).

FIG. 5 illustrates an exemplary schematic representation of a section of a semiconductor device 3a with a plurality of (here: two) different one time programmable elements 3101a, 3101b in accordance with a further additional embodiment.

The two different one time programmable elements 3101a, 3101b form together an element group 3101 by using which it is possible to store a bit of information—or ly also a plurality of bits of information (see below)—in the manner that will be explained in more detail in the following.

As results from FIG. 5, the element group 3101 may include an e-fuse resistor 3101a—that is constructed correspondingly similar to a conventional e-fuse resistor—, and a laser fuse resistor 3101b—that is constructed correspondingly similar to a conventional laser fuse resistor—, etc.

As results further from FIG. 5, the two different one time programmable elements 3101a, 3101b of the element group 3101 are connected in parallel.

For instance, a first connection of the e-fuse resistor 3101a may be connected to a supply voltage (here: Vdd).

Furthermore, a first connection of the laser fuse resistor 3010b may be grounded, i.e. be connected to ground potential (GND).

A second connection of the e-fuse resistor 3101a my be connected to a first connection of a resistor 311b with an ohmic resistance R1, and be grounded, i.e. be connected to the above-mentioned ground potential (GND), via a corresponding resistor 3111d.

Correspondingly similar, the second connection of the laser fuse resistor 3101b may be connected to a first connection of a resistor 3111c with an ohmic resistance R2, and be grounded, i.e. be connected to the above-mentioned ground potential (GND), via a corresponding resistor 3111e.

The second connection of the resistor 3111b and the second connection of the resistor 3111c may be connected with each other and possibly be grounded, i.e. be connected to the ground potential (GND), via a corresponding resistor 3111a (with an ohmic resistance R).

Furthermore, the second connections of the resistors 3111b, 3111c may—jointly—be connected to a corresponding converter means that converts the analog value present at the second connections of the resistors to a corresponding digital one-bit value (“0”, or “1”), or—alternatively—to a corresponding digital two-bit value (e.g., “00”, or “01”, or “10”, or “11” (see below)).

In a first (initial) state of the element group 3101, all programmable elements 3101a, 3101b may be in the above-mentioned first, conductive state (“non-programmed state”).

At the second connections of the resistors 3111b, 3111c—i.e. at the output of the element group 3101—the following voltage potential Vout will then be present:

Vout=Vdd×R2/(R1+R2)

This voltage potential may be converted by the above-mentioned converter means, for instance, to a corresponding one-bit value, or, for instance, to a corresponding two-bit value.

If a different one- (or two-) bit value is to be stored instead by the element group 3101, the element group 3101 may be placed from the above-mentioned first (initial) state in a second state.

To this end—correspondingly similar as explained above—optionally either the laser fuse resistor 3010b, or—in one embodiment also only in a relatively late stage of the manufacturing process—the e-fuse resistor 3101a of the element group 3101 may be placed from the above-mentioned conductive, first state (“non-programmed state”) in a non-conductive, second state (“programmed state”).

In the above-mentioned second state of the element group 3101, thus either the e-fuse resistor 3101a or the laser fuse resistor 3101b is in the above-mentioned second, non-conductive state (“programmed state”), and the respectively other resistor in the above-mentioned first, conductive state (“non-programmed state”).

At the second connections of the resistors 3111b, 3111c—i.e. at the output of the element group 3101—if the e-fuse resistor 3101a is programmed, the ground potential GND will then be present.

This voltage potential may be converted by the above-mentioned converter means to a corresponding one-bit value—in one embodiment a one-bit value differing from the above-mentioned one-bit value—, or .g., to a corresponding two-bit value (in one embodiment a two-bit value differing from the above-mentioned two-bit value).

If the laser fuse resistor 3101b is programmed instead of the e-fuse resistor 3101a, the supply voltage potential Vdd is present at the second connections of the resistors 3111b, 3111c—i.e. at the output of the element group 3101.

This voltage potential may be converted by the above-mentioned converter means to a corresponding one-bit value—in one embodiment a one-bit value differing from the above-mentioned one-bit value—, or e.g., to a corresponding two-bit value (in one embodiment a two-bit value differing from the above-mentioned two-bit value).

If the element group 3101 is placed from the above-mentioned second state in a third state in which both resistors 3101a, 3101b are in the above-mentioned non-conductive, second state (“programmed state”), the second connections of the resistors 3111b, 3111c—i.e. the output of the element group 3101—are/is in a “floating” state.

In a further variant of the invention, the second connections of the resistors 3111b, 3111c are not or not directly connected with each other. Instead, the second connection of the resistor 3111b may be connected to a first converter means, and the second connection of the resistor 3111c to a corresponding second converter means.

The converter means convert the analog value present at the respective second connections of the resistors 3111b, 3111c to a corresponding digital bit value (logic “0”, or logic “1”).

The digital bit value output by the first converter means may be fed to a first input of an evaluation logic circuit—that is constructed correspondingly similar to the evaluation logic circuit illustrated in FIG. 2—, e.g., to the first input of a corresponding OR-, XOR-, or AND gate, and the digital bit value output by the second converter means to a second input of the evaluation logic circuit, e.g., the second input of the corresponding OR-, XOR-, or AND gate. The output of the evaluation logic circuit, e.g., of the OR-, XOR-, or AND gate, forms the output of the element group 3101 at which a corresponding digital output signal out may be tapped.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device comprising:
a plurality of different one-time programmable elements that form a group of one-time programmable elements, wherein at least one bit of information is stored jointly by the plurality of different one time programmable elements of the group.

2. The semiconductor device of claim 1, wherein the group of one time programmable elements comprises at least two different one time programmable elements.

3. The semiconductor device of claim 1, comprising wherein the one time programmable elements are fuse resistors.

4. The semiconductor device of claim 1, comprising wherein a first of the plurality of different one time programmable elements is a laser fuse resistor, and a second of the plurality of different one time programmable elements is an e-fuse resistor.

5. The semiconductor device of claim 2, comprising wherein the at least two different one time programmable elements are connected in parallel.

6. The semiconductor device of claim 2, comprising wherein the at least two different one time programmable elements are connected in series.

7. The semiconductor device of claim 1, comprising:
evaluation measure for determining that a bit “0” is stored as information by the group if all one time programmable elements of the group are in a non-programmed state.

8. The semiconductor device of claim 7, comprising wherein the evaluation measure determines that a bit “1” is stored as information by the group if at least one of the one time programmable elements of the group is in a programmed state.

9. The semiconductor device of claim 1, comprising:
evaluation measure for determining that a bit “1” is stored as information by the group if all one time programmable elements of the group are in a non-programmed state.

10. The semiconductor device of claim 9, comprising wherein the evaluation measure determines that a bit “0” is stored as information by the group if at least one of the one time programmable elements of the group is in a programmed state.

11. The semiconductor device of claim 1, comprising evaluation measure comprising an OR-, XOR-, or AND gate.

12. The semiconductor device of claim 1, comprising wherein a first of the plurality of different one time programmable elements is connected to a supply voltage potential, and a second of the plurality of different one time programmable elements is connected to ground potential.

13. The semiconductor device of claim 1, comprising a RAM.

14. The semiconductor device of claim 13, comprising a DRAM.

15. The semiconductor device of claim 13, comprising an SRAM.

16. An electronic system comprising:
a semiconductor device; and
a plurality of different one-time programmable elements that form a group of one-time programmable elements, wherein at least one bit of information is stored jointly by the plurality of different one time programmable elements of the group.

17. A method for programming a semiconductor device comprising:
defining a plurality of different one time programmable elements that form a group of one time programmable elements, wherein the plurality of different one time programmable elements of the group jointly store a bit of information; and
leaving the one time programmable elements of the group in a non-programmed state if a bit “0” is to be stored as information by the group.

18. The method of claim 17, comprising:
programming a first or a second of the different one time programmable elements of the group, if a bit “1” is to be stored as information by the group.

19. A method for programming a semiconductor device comprising:
defining a plurality of different one time programmable elements that form a group of one time programmable elements, wherein the plurality of different one time programmable elements of the group jointly store a bit of information; and
leaving the one time programmable elements of the group in a non-programmed state if a bit “1” is to be stored as information by the group.

20. The method of claim 19, comprising:
programming a first or a second of the different one time programmable elements of the group if a bit “0” is to be stored as information by the group.

21. The method of claim 19, comprising wherein the one time programmable elements are fuse resistors.

22. The method of claim 21, comprising wherein the first of the different one-time programmable elements is a laser fuse resistor, and the second of the different one time programmable elements is an e-fuse resistor.

23. A method for operating a semiconductor device comprising:
defining a plurality of different one time programmable elements that form a group of one time programmable elements, wherein a bit of information is jointly stored by the plurality of different one time programmable elements of the group; and
determining whether a bit “1” or “0” is stored by the one time programmable elements of the group.

24. The method of claim 23, comprising determining that a bit “0” is stored by the one time programmable elements of the group if all one time programmable elements of the group are in a non-programmed state.

25. The method of claim 23, comprising determining that a bit “1” is stored by the one time programmable elements of the group if at least one of the one time programmable elements of the group is in a programmed state.
